(19) United States
(12) Patent Application Publication
(10) Pub. No.: US 2013/0216699 A1
(43) Pub. Date: Aug. 22, 2013

(54) METHOD AND APPARATUS FOR FILLING METAL PASTE, AND METHOD FOR FABRICATING VIA PLUG

(71) Applicant: Tokyo Electron Limited, (US)

(72) Inventors: Eiji Yamaguchi, Yamanashi (JP); Michikazu Nakamura, Yamanashi (JP); Muneo Harada, Iwate (JP)

(73) Assignee: TOKYO ELECTRON LIMITED, Tokyo (JP)

(21) Appl. No.: 13/766,838

(22) Filed: Feb. 14, 2013

(30) Foreign Application Priority Data
Feb. 17, 2012 (JP) 2012-033017

(51) Int. Cl. H05K 3/00

(52) U.S. Cl. CPC H05K 3/0094
USPC 427/97.8; 118/58

(57) ABSTRACT

Disclosed is a metal paste filling apparatus that fills the metal paste in a non-through hole of a substrate conveniently and efficiently without producing a void.

The metal paste filling apparatus includes a pad, an exhaust unit, a metal paste supply unit, and a controller. One or more exhaust ports and one or more inlet ports are formed in the acting surface of the pad. The exhaust unit includes a vacuum apparatus connected to a gas flow path in the pad through an exhaust tube, and a direction switching valve installed in the way of the exhaust tube. The metal paste supply unit includes a syringe unit connected to a paste flow path in the pad. The syringe unit includes a paste container, a compressed air supply source, a suck-back valve, and a regulator.

### CROSS-REFERENCE TO RELATED APPLICATIONS

This application is based on and claims priority from Japanese Patent Application No. 2012-033017, filed on Feb. 17, 2012, with the Japanese Patent Office, the disclosure of which is incorporated herein in its entirety by reference.

### TECHNICAL FIELD

The present disclosure relates to an integrated circuit mounting technology, and more particularly to a method and apparatus for filing a metal paste in a non-through hole of a substrate, and a method for fabricating a via plug in a via of the substrate.

### BACKGROUND

As electronic devices are miniaturized and made to be portable and to exhibit high-performance functions recently, a three-dimensional mounting is expected that stacks silicon substrates in multiple layers. In particular, a TSV (Through Silicon Via) technology receives attention as a three-dimensional mounting technology that may readily realize a high density, high capacity and high performance. The TSV technology performs inter-chip circuit connection using a TSV that penetrates through the silicon substrate.

In general, TSV processing processes are classified into two types according to the sequence of steps in a wafer process. i.e. into a via-first performed prior to a wiring process (BEOL (Back End Of Line)) and a via-last performed after the BEOL. The via-first is advantageous for micromachining, and may readily reduce the diameter of a via or form a plurality of TSVs. However, the via-first has a restriction in that the conductor of the via is limited to a polysilicon with a high resistivity. On the contrary, the via-last has a difficulty in reducing the diameter of a via and in increasing the number of TSVs. However, the via-last has advantages in that Ag (silver) or Cu (copper) with a low resistivity may be used as the conductor of a via, and the degree of freedom of design is high. Up to now, plating is used in order to fill a conductor in a non-through via in the TSV fabrication process of the via-last. See, for example, Japanese Patent Laid-open Publication No. 2011-40457.

### SUMMARY

According to the first point of view of the present disclosure, there is provided a metal paste filling method for filling a metal paste in one or more non-through holes formed in a surface of a substrate. The metal paste filling method includes: locating an acting surface of a pad opposite to the surface of the substrate with a gap therebetween in such a manner that the acting surface of the pad covers at least one of the non-through holes, the gap being smaller than a predetermined threshold value in relation to the surface of the substrate; decompressing the inside of the gap by discharging the air in the gap from one or more exhaust ports formed in the acting surface of the pad; and supplying the metal paste from one or more inlet ports formed in the acting surface of the pad to the non-through holes existing in the gap.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 illustrates a configuration of a metal paste filling apparatus according to a first aspect of the present disclosure.

FIG. 2 is a partial cross-sectional view illustrating a construction of a silicon substrate in a step of a TSV processing process.

FIG. 3 is a perspective view illustrating the metal paste filling apparatus in a state where a pad is located opposite to a semiconductor chip.

FIG. 4 is a cross-sectional view illustrating an aspect of an exemplary embodiment in the metal paste filling apparatus where the workpiece is a semiconductor chip.

FIG. 5A illustrates the first step of the metal paste filling processing in the exemplary embodiment of FIG. 4.

FIG. 5B illustrates the second step of the metal paste filling processing in the exemplary embodiment of FIG. 4.

FIG. 5C illustrates the third step of the metal paste filling processing in the exemplary embodiment of FIG. 4.

FIG. 5D illustrates the fourth step of the metal paste filling processing in the exemplary embodiment of FIG. 4.

FIG. 6A illustrates a cross-sectional structure of a semiconductor chip prior to a baking processing.

FIG. 6B illustrates the cross-sectional structure of the semiconductor chip after the baking processing.

FIG. 6C illustrates the cross-sectional structure of the semiconductor chip after removing the mask from the surface of the semiconductor chip to be processed.

FIG. 7A illustrate the step of ablating the rear surface of the silicon substrate until the bottom portion of the via plug formed in a non-through via of the substrate is exposed in the TSV fabricating process as illustrated in FIG. 2.

FIG. 7B illustrate the step of forming or attaching metal bumps on the top and bottom surfaces of the via plug fabricated in the silicon substrate in the TSV fabricating process as illustrated in FIG. 2.

FIG. 8A is a perspective view illustrating a principle part of an exemplary embodiment in the metal paste filling apparatus where the workpiece is a semiconductor wafer.

FIG. 8B is a perspective view illustrating of a principle part of another exemplary embodiment in the metal paste filling apparatus where the workpiece is a semiconductor wafer.

FIG. 9 illustrates a configuration of a principle part of a modified embodiment in the metal paste filling apparatus.

FIG. 10 illustrates a configuration of a principle part of another modified embodiment in the metal paste filling apparatus.

FIG. 11 illustrates a configuration of a principle part of another modified embodiment in the metal paste filling apparatus.

FIG. 12 illustrates a principle part of another modified embodiment in the metal paste filling apparatus.

FIG. 13 illustrates a principle part of another modified embodiment in the metal paste filling apparatus.

FIG. 14 illustrates a configuration of a metal paste filling apparatus according to a second aspect of the present disclosure.

FIG. 15 is a perspective view illustrating a construction of a head in the metal paste filling apparatus.

FIG. 16 is a perspective view illustrating the construction of a main part of the head.

FIG. 17 is a perspective of an exemplary embodiment in the metal paste filling apparatus where the workpiece is a semiconductor wafer.

FIG. 18A illustrates the first step of the metal paste filling processing in the exemplary embodiment of FIG. 17.

FIG. 18B illustrates the second step of the metal paste filling processing in the exemplary embodiment of FIG. 17.

FIG. 18C illustrates the third step of the metal paste filling processing in the exemplary embodiment of FIG. 17.

FIG. 18D illustrates the fourth step of the metal paste filling processing in the exemplary embodiment of FIG. 17.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made, without departing from the spirit or scope of the subject matter presented here.

However, the plating costs high and requires a large-scale electro-plating apparatus. Furthermore, the plating requires that a seed layer for a plating electrode as well as an insulation film for a partition be formed on an inner wall of a non-through via. As a result, the plating requires a sputtering apparatus to form the seed layer. In addition, a via of a TSV is generally formed to have a micro diameter of not more than 50 μm. For this reason, it is also a problem to be solved that it is difficult to fill the non-through via of the TSV from the bottom portion to the top portion thereof without any void through plating. In addition, the plating grows the plated metal to a height where the plated metal protrudes to the top and outside of the via, and then the plated metal within the via is made to coincide with the level of the surface of the substrate by a chemical and mechanical polishing (CMP). Accordingly, the post-processing is also complicated and costs high.

The present disclosure was made in an effort to solve the problems in the prior art and provides a metal paste filling method and metal paste filling apparatus capable of conveniently and efficiently filling a metal paste in a non-through hole in a substrate.

In addition, the present disclosure provides a metal paste filling method and metal paste filling apparatus capable of filling a metal paste in a non-through hole in a substrate without a void.

Moreover, the present disclosure provides a via plug fabricating method capable of conveniently and efficiently fabricating a via plug of a conductor in a non-through hole of a substrate to conform to the level of a surface of the substrate to be processed.

According to the first point of view of the present disclosure, there is provided a metal paste filling method for filling a metal paste in one or more non-through holes formed in a surface of a substrate. The metal paste filling method includes: locating an acting surface of a pad opposite to the surface of the substrate with a gap therebetween in such a manner that the acting surface of the pad covers at least one of the non-through holes, the gap being smaller than a predetermined threshold value in relation to the surface of the substrate; decompressing the inside of the gap by discharging the air in the gap from one or more exhaust ports formed in the acting surface of the pad; and supplying the metal paste from one or more inlet ports formed in the acting surface of the pad to the non-through holes existing in the gap.

In the metal paste filling method, the threshold value is a gap distance when the total of side area of the gap formed between the acting surface of the pad and the surface of the substrate becomes the total of bore area of the exhaust ports.

In the metal paste filling method, in the metal paste supplying step, an exhaust operation through the exhaust ports is continued until the metal paste widely spreads to the all or some of the non-through holes within the gap, and the exhaust operation is stopped after the metal paste widely spreads to all or some of the non-through holes within the gap.

In the metal paste filling method, in the metal paste supplying step, the exhaust ports are opened to the atmosphere just after or simultaneously when the exhaust operation is stopped.

In the metal paste filling method, just after the metal paste supplying step is terminated, the acting surface of the pad is urged against the surface of the substrate.

In the metal paste filling method, the substrate is a single semiconductor chip cut from a semiconductor wafer as an individual piece, and in the acting surface locating step, the pad covers all or some of the non-through holes formed on the surface of the semiconductor chip, in the decompressing step, all or some of the non-through holes of the semiconductor chip are decompressed, and in the metal paste supplying step, the metal paste is filled in all or some of the non-through holes of the semiconductor chip at once.

In the metal paste filling method, the substrate is a semiconductor wafer, and wherein in the acting surface locating step, the pad covers all or some of the non-through holes formed in one cell region or a plurality of continued cell regions on the semiconductor wafer, in the decompressing step, the inside of all or some of the non-through holes in the cell region(s) are decompressed, and in the metal paste supplying step, the metal paste is filled in all or some of the non-through holes in the cell region(s) at once.

In the metal paste filling method, the substrate is a semiconductor wafer, and wherein in the acting surface locating step, the pad covers all or some of the non-through holes formed in a divided region of one unit on the semiconductor wafer when the semiconductor wafer is divided in a matrix form with reference to the acting surface of the pad, and in the metal paste supplying step, the metal paste is filled in all or some of the non-through holes in the divided region of one unit at once.

In the metal paste filling method, the bore of the non-through holes is in the range of 5 μm to 50 μm.

In the metal paste filling method, the metal paste contains metal nano-particles.

In addition, according to the first point of view of the present disclosure, there is provided a metal paste filling apparatus for filling a metal paste in one or more non-through holes formed in a surface of substrate. The metal paste filling apparatus includes: a pad including an acting surface that is located opposite to the surface of the substrate with a gap therebetween in such a manner that the acting surface covers at least one of the non-through vias, the gap being smaller than a predetermined threshold value in relation to the surface of the substrate; an exhaust unit including one or more exhaust ports formed in the acting surface of the pad, and configured to discharge the air within the gap through the exhaust ports to decompress the inside of the gap; and a metal paste supply unit including one or more inlet ports formed in the acting surface of the pad, and configured to supply the metal paste from the inlet ports to all or some of the non-through holes existing in the gap.

In the metal paste filling apparatus, the acting surface of the pad is flat.

In the metal paste filling apparatus, the exhaust unit includes: a gas flow path extending through the pad to be connected with the exhaust ports; and a vacuum apparatus connected with the gas flow path through an exhaust tube.

In the metal paste filling apparatus, a switching valve is installed in the way of the exhaust tube so as to selectively connect the exhaust ports to one of the vacuum apparatus or an air port.

In the metal paste filling apparatus, the metal paste supply unit includes: a paste flow path extending through the pad to be connected with the inlet ports; and a syringe unit configured to compress and supply metal paste to the paste flow path through a paste supply tube.

In the metal paste filling apparatus, the syringe unit includes: a paste container including an outlet connected to the paste flow path and an inlet formed opposite to the outlet, and configured to accommodate a metal paste; and a compressed gas supply source connected to the inlet of the paste container through a gas tube.

In the metal paste filling apparatus, the syringe unit includes a suck-back valve installed in the way of the gas tube.

In the metal paste filling apparatus, a bank part is formed on the acting surface of the pad to surround at least a part of the non-through holes of the substrate when the pad is located to be opposite to the substrate with the gap therebetween.

In the metal paste filling apparatus, the bank part protrudes from the acting surface of the pad with a height of not more than 0.5 mm.

In the metal paste filling apparatus, the bank part has a slidable characteristic in relation to the substrate.

In the metal paste filling apparatus, a labyrinth groove is formed on the acting surface of the pad to surround at least a part of the non-through vias of the substrate when the pad is located to be opposite to the substrate with the gap therebetween.

The metal paste filling apparatus further includes a displacement mechanism to conduct relative positioning, opposite locating, and separating between the substrate and the pad.

In the first point view of the present disclosure, since the surface of the substrate and the acting surface of the pad are located opposite to each other with a gap therebetween that is smaller than the predetermined threshold value, and the air within the gap is discharged by the exhaust unit through the exhaust ports, the air discharge rate from the gap exceeds the air inflow rate into the gap, thereby reducing the air within the gap. As a result, the insides of the gap and the non-through holes are turned into a decompressed condition. In this state, the metal paste supply unit supplies the metal paste into the gap through the inlet port in the acting surface of the pad. The metal paste introduced from the inlet port rapidly spreads in all directions within the gap that is in the decompressed condition, and in the process of spreading, the metal paste flows into each non-through bore wherever the metal paste goes. In that event, since the inside of the non-through hole is also in the decompressed condition, the metal paste smoothly flows into the non-through hole and is filled in the non-through hole.

According to the second point of view of the present disclosure, there is also provided a metal paste filling method for filling a metal paste in one or more non-through holes formed in a surface of a substrate. The metal paste filling method includes: locating an acting surface of a head opposite to the surface of the substrate, where the acting surface of the head is formed with a gas flow path of a groove shape configured to allow a suction gas to flow therein, and a paste discharge port of a groove shape configured to discharge the metal paste to the outside; supplying gas flow from the outside to let the gas flow out of the gas flow path; compressing and supplying the metal paste to the paste discharge port; and relatively sliding the head on the surface of the substrate in such a manner that the gas flow path firstly passes over at least one of the non-through vias of the substrate to decompress the inside of the at least one non-through via by the venturi effect, and then the paste discharge port passes over the at least one non-through via to fill the metal paste in the inside of the at least one non-through via.

According to the second point of view, there is also provided a metal paste filling apparatus for filling a metal paste in one or more non-through holes formed in a surface of a substrate. The metal paste filling apparatus includes: a head including an acting surface that is formed with a gas flow path of a groove shape configured to allow a suction gas to flow therein, and a paste discharge port of a groove shape configured to discharge the metal paste to the outside; a gas flow supply unit configured to supply gas flow from the outside to let the gas flow out of the gas flow path; a metal paste supply unit configured to compress and supply the metal paste to the paste discharge port; and a displacement mechanism configured to relatively slide the head on the surface of the substrate in such a manner that the gas flow path firstly passes over at least one of the non-through vias of the substrate to decompress the inside of the at least one non-through via by the venturi effect, and then the paste discharge port passes over the at least one non-through via to fill the metal paste in the inside of the at least one non-through via.

In the second point of view of the present disclosure, the displacement mechanism is operated to scan the head on the substrate. During the scanning of the head, the air flow supply unit and the metal paste supply unit are continuously operated in an ON state. In the process of displacing the head on the substrate, the air flow path of the acting surface of the head firstly passes over each non-through hole existing wherever the head goes. In that event, since the air flow supplied from the air flow supply unit flows out of the air flow path, the air within the non-through hole just below the air flow path is drawn out (suctioned) into the air flow path such that the inside of the non-through hole is turned into a decompressed condition. Directly after this, the paste discharge port of the acting surface of the head passes over the non-through hole that maintains the decompressed condition. Then, the metal paste flows into the non-through hole from the paste discharge port by being suctioned such that the non-through via is filled with the metal paste.

According to another aspect of the present disclosure, there is provided a via plug fabricating method. The via plug fabricating method is a method of fabricating a metal plug of a conductor in one or more non-through vias formed in a surface of a substrate. The via plug fabricating method includes: depositing a mask on a surface of the mask to be processed, where the mask is formed with one or more openings at the positions superimposed with the non-through vias, respectively, and the bore of the openings is the same as that of the non-through vias; filling a metal paste in each of the non-through vias from the bottom portion to the top portion thereof; baking the metal paste filled in the non-through vias by heating the substrate at a predetermined temperature such that the metal paste is turned into one or more solid via plugs; and removing the mask from the surface of the substrate to be processed.

In the plug fabricating method, the metal paste filling step includes: locating an acting surface of a pad opposite to the surface of the substrate with a gap smaller than a predetermined threshold value in relation to the surface of the substrate in such a manner that the acting surface covers at least one of the non-through holes; decompressing the inside of the gap by discharging the air in the gap from one or more exhaust ports formed in the acting surface of the pad; and supplying the metal paste from one or more inlet ports formed in the acting surface of the pad to all or some of the non-through holes existing in the gap.

In the plug fabricating method, the metal paste filling step includes: locating an acting surface of a head opposite to the surface of the substrate, where the acting surface of the head is formed with a gas flow path of a groove shape configured to allow a suction gas to flow therein, and a paste discharge port of a groove shape configured to discharge the metal paste; supplying gas flow from the outside to let the gas flow out of the gas flow path; compressing and supplying the metal paste to the paste discharge port; and relatively sliding the head on the surface of the substrate in such a manner that the gas flow path passes over at least a part of the non-through vias of the substrate first to decompress the insides of the non-through vias by the venturi effect, and then the paste discharge port passes over the non-through vias to fill the metal paste in the insides of the non-through vias.

In the plug fabricating method, the thickness of the mask is determined in such a manner that the metal paste filled in the non-through vias from the bottom portion thereof to the top portion of the openings of the mask is contracted by the metal paste baking step to a height where the top surface of the metal paste filled in the non-through vias becomes coplanar with the surface of the substrate to be processed.

In the via plug fabrication method of the present disclosure, if the metal paste, which has been filled in the non-through vias and overflowed to the surface of the substrate in the metal paste filling step, is wiped, for example, by a squeeze, the top surface of the metal paste filled in the non-through vias becomes substantially coplanar with the top surface of the openings of the mask. Thereafter, if the substrate is heated in the metal paste baking step, a flux volatilizes from the metal paste filled in the non-through vias and the metal paste is turned into solid via plugs. Since the volume of the metal paste filled in the non-through vias is reduced due to the volatilization of the flux when the metal paste is turned into the solid via plugs in this manner, the top surface of the via plugs becomes lower than the top surface of the mask. For example, the thickness of the mask is determined in such a manner that in the metal paste baking step, the metal paste filled in each non-through via from the bottom portion to the top portion thereof contracts to a height where the top surface of the metal paste becomes coplanar with the surface of the substrate to be processed. As such, when the mask is removed from the surface of the substrate to be processed after the baking processing is terminated, the top surface of the via plugs fabricated in the non-through holes is exposed at a level that is matched with the surface of the substrate to be processed, for example, to be coplanar with the surface of the substrate to be processed.

According to the metal paste filling method and a metal paste filling apparatus of the present disclosure, a metal paste is filled in a non-through via in a substrate conveniently and efficiently with the above-described configurations and functional actions. Furthermore, the metal paste is filled in the non-through hole of the substrate without a void.

According to the via plug fabrication method of the present disclosure, a via plug of a conductor is fabricated in a non-through via in a substrate conveniently and efficiently to be mated with the level of the surface of the substrate to be processed with the above-described configurations and functional actions.

### [First Aspect]

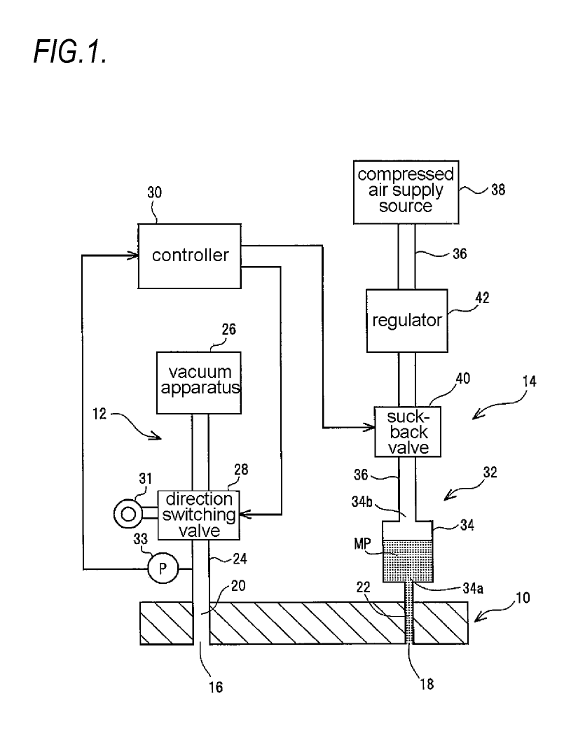

Hereinbelow, a first aspect of the present disclosure will be described with reference to FIGS. 1 to 13.

FIG. 1 illustrates a construction of a metal paste filling apparatus according to the first aspect. The main metal paste apparatus includes a pad 10, an exhaust unit 12, a metal paste supply unit 14, and a controller 30, as main constructional elements.

Pad 10 may be formed from a rigid material that has an excellent machinability, for example, in mirror-like finishing or drilling, and is highly resistant against a metal paste flux, for example, alcohol. For example, pad 10 may be formed from a stainless steel, an aluminum, a resin, or a glass. Pad 10 has an acting surface 10a with a high flatness. The shape and size of the pad may be optional. However, as described below, when filling all the vias in a single semiconductor chip with a metal paste at once, it is preferred that pad 10 has a shape and size that are equal or at least similar to those of the semiconductor chip, or a shape and size which are larger than those of the semiconductor chip when they are viewed in a top plan view. Although the thickness of pad 10 may also be optional, a flat plate or block with a thickness of 5 mm to 50 mm may be suitably selected.

At least one exhaust port 16, which is a constitutional element of exhaust unit 12, and at least one inlet port 18, which is a constitutional element of metal paste supply unit 14, are formed on acting surface 10a of pad 10 with an interval therebetween. Typically, pad 10 is formed with one exhaust port 16 and one inlet port 18 at opposite peripheral parts thereof. However, the numbers and arrangement positions of exhaust port 16 and inlet port 18 may be optionally determined.

Pad 10 is formed with a gas flow path 20 and a paste flow path 22 at the positions which correspond to exhaust port 16 and inlet port 18, respectively. Gas flow path 20 and paste flow path 22 extend through pad 10 in the thickness direction and are connected with exhaust port 16 and inlet port 18 with the same bore, respectively. Gas flow path 20 and paste flow path 22 also serve as the constitutional elements of exhaust unit 12 and metal paste supply unit 14, respectively.

The bore of exhaust port 16 is determined based on, for example, the number of exhaust ports 16, the effective area of pad acting surface 10a, the number of non-through holes covered by pad acting surface 10a, and the profile of the non-through holes. For example, exhaust port 16 has a bore size of 1 mm to 5 mm. Bore of inlet port 18 is also determined based on, for example, the number of inlet ports 18, the effective area of pad acting surface 10a, the number of non-through holes covered by pad acting surface 10a, the profile of the non-through holes, the viscosity of the metal paste, and the supply amount of one dose. For example, inlet port 18 has a bore size of 100 μm to 1 mm.

Exhaust unit 12 includes a vacuum apparatus 26 connected to gas flow path 20 in pad 10 through an exhaust tube 24, and a direction switching valve 28 installed in the way of exhaust tube 24. Vacuum apparatus 26 is constituted by, for example, a vacuum pump or an ejector. Direction switching valve 28 is configured to be capable of selectively connecting gas flow path 20 to one of the outlet side of vacuum apparatus 26 and an air port 31 under the control of a controller 30. In addition, a pressure sensor 33 is provided to measure the pressure in exhaust tube 24, in which an output signal of pressure sensor 33 is adapted to be sent to controller 30.

Metal paste supply unit 14 includes a syringe unit 32 connected to paste flow path 22 in pad 10. Syringe unit 32 includes: a paste container 34, of which outlet 34a is connected to paste flow path 22; a compressed air supply source 38 connected to inlet 34b of paste container 34, which is formed opposite to outlet 34a of paste container 34, through gas tube 36; and a such-back valve 40 and a regulator 42 installed in the way of gas tube 36.

Paste container 34 accommodates a metal paste (MP) in a cartridge exchange type or replenishment type. Compressed air supply source 38 may be a compressor or a factory power. Suck-back valve 40 includes an open/close valve with a suck-back function, and is controlled by controller 30. Regulator 42 regulates the pressure of compressed air supplied from compressed air supply source 38 to paste container 34.

Controller 30 includes a microcomputer and a required interface or peripheral device, and controls an action or condition of each of the units in the metal paste filling apparatus, and the sequence of the entirety of the metal paste filling apparatus. Although not illustrated, a pad displacement mechanism may be provided as a constitutional element of the metal paste filling apparatus, in which the pad displacement mechanism may support pad 10, and may conduct, for example, positioning, opposite locating, and separating of pad 10 in relation to a substrate to be processed. In such a case, controller 30 controls the action of the pad displacement mechanism.

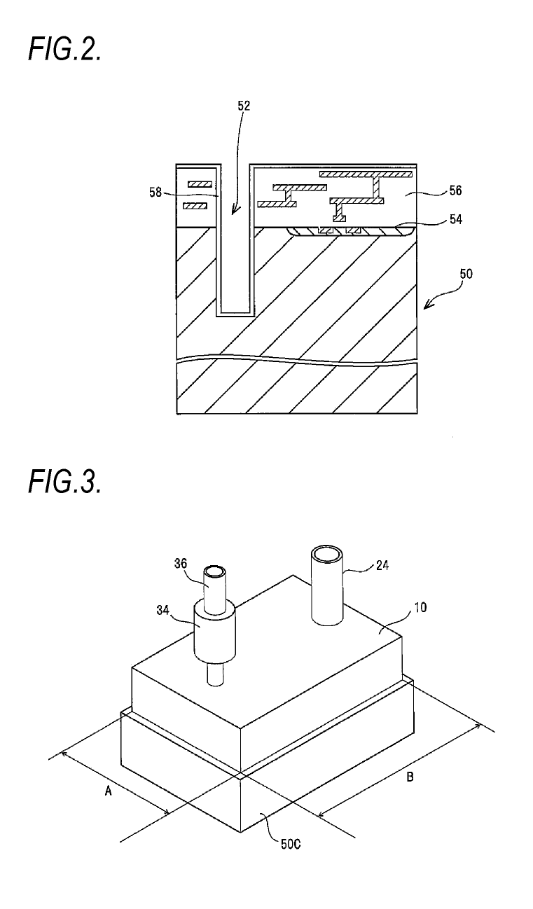

For example, as illustrated in FIG. 2, the metal paste filling apparatus is used for a via plug fabrication process, in which a silicon substrate 50 with at least one non-through via 52 formed in a surface (a surface to be processed) in a via-last TSV process is used as a substrate to be processed, and each non-through via 52 of silicon substrate 50 is filled with the metal paste. As the metal paste, a metal nano-particle paste with a low resistivity, for example, a silver nano-particle paste and a copper nano-particle paste, may be properly used.

In FIG. 2, a semiconductor device 54, for example, a transistor is incorporated in a device forming surface of silicon substrate 50, and a multilayered wiring structure 56 is formed on the device forming surface. Non-through via 52 is perforated at a desired position on the surface of silicon substrate 50, i.e. the device forming surface side with a desired bore and depth by a dry etching or a laser beam processing. Typically, on the inner wall of non-through via 52, an insulation film, for example, a silicon oxide film 58 is formed through chemical vapor deposition (CVD) in order to isolate a via conductor or a via plug from Si of silicon substrate 50. The bore of non-through via 52 is, for example, 5 μm to 50 μm, and the depth is, for example, 30 μm to 120 μm. Silicon substrate 50 has a thickness of, for example, 700 μm. As described below, after the via plug fabrication process, the thickness of the substrate is reduced until the bottom portion of non-through via 52 (i.e., the bottom portion of via plug) is exposed from the rear side of the substrate. For example, the thickness of the substrate may be reduced to a thickness of 100 μm.

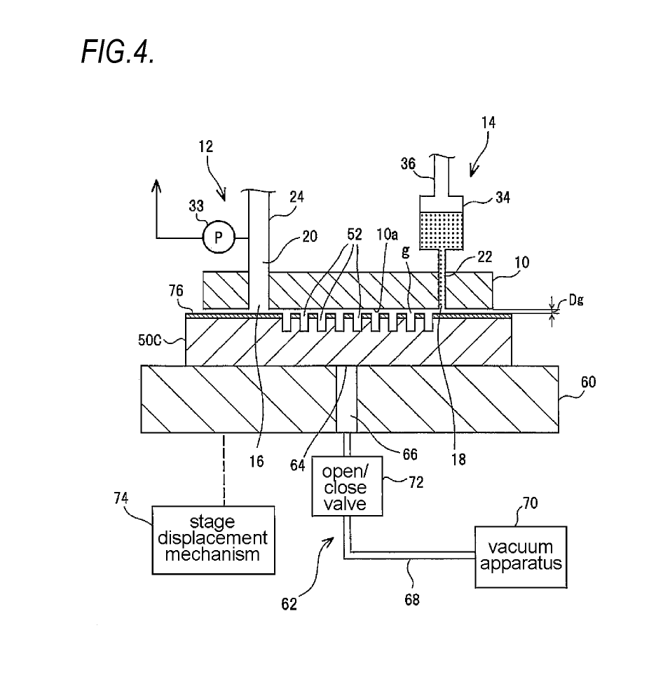

Next, with reference to FIGS. 3 to 7B, an exemplary embodiment in the metal paste filling apparatus will be described in which the silicon substrate 50 to be processed (a workpiece) is a single semiconductor chip (die) 50C that is one of individual pieces cut out from the semiconductor wafer. In the present exemplary embodiment, all non-through vias 52 formed in the surface of semiconductor chip 50C are filled with metal paste at once. Meanwhile, in FIGS. 4 to 6C, a semiconductor device 54, a multi-layered wiring structure 56, and a silicon oxide film 58 on semiconductor chip 50C are omitted for the convenience of illustration.

As illustrated in FIGS. 3 and 4, in the present exemplary embodiment, in the first step, acting surface 10a of pad 10 is located opposite to and parallel to the surface of semiconductor chip 50C with a gap g therebetween in such a manner that acting surface 10a of pad 10 covers all non-through vias 52 distributed on the surface of semiconductor chip 50C in parallel. Gap g has a distance D_{g} smaller than a threshold value D_{G} predetermined in relation to the surface of semiconductor chip. In that event, semiconductor chip 50C is fixed on a stage 60 to be faced up.

In order to removably fix semiconductor ship 50C, stage 60 is provided with, for example, a vacuum mechanism 62. Vacuum mechanism 62 includes an adsorption port 64 formed in the top surface of stage 60, and a vacuum apparatus 70 connected to adsorption port 64 through vacuum passage 66 extending through stage 60 and an external vacuum tube 68. An open/close valve 72 is installed in the way of vacuum tube 68. Vacuum apparatus 70 is constituted by a vacuum pump or an ejector device. In addition, a stage displacement mechanism 74 may be provided to displace stage 60 in some or all of X, Y, Z, and θ directions. Vacuum mechanism 62 and stage displacement mechanism 74 are also operated under the control of controller 30 (see FIG. 1).

In the present exemplary embodiment, a mask 76 is deposited on the surface to be processed on semiconductor 50C in advance. Mask 76 is formed with openings at positions which are superimposed on non-through vias 52, respectively, where the bore of the openings is the same as that of the non-through vias. Mask 76 is removed after the via plugs are completed through a baking processing after the filling processing of metal paste, and the thickness of the mask has an important meaning as described below. As the material of mask 76, a material is preferable that is excellent in resistance against the metal paste flux and heat resistance, and allows efficient deposition and peeling off in relation to the surface of semiconductor chip 50C. For example, a resist or a dry film may be suitably used. Accordingly, while mask 76 is being deposited on the surface to be processed on semiconductor chip 50C, the top surface of mask 76 serves as the surface of semiconductor chip 50C.

As described above, in abutting semiconductor chip 50C and pad 10, it is important to form gap g therebetween in which gap has a distance D_{g} smaller than a threshold value D_{G}. Here, threshold value D_{G} is a gap distance (height) when the total of side area S_{g} of gap g is equal to the total of bore area S₁₆ of exhaust ports 16.

For example, assuming that the shape of pad 10 is rectangular or square when in a plan view as illustrated in FIG. 3, and the lengths of the short side and long side of pad 10 are A and B, respectively, the total of side area S_{g} of gap g is S_{g}=D_{g}×2(A+B). Meanwhile, assuming that the number of exhaust ports 16 is, for example, one, and its bore (diameter) is R₁₆, the total of bore area S16 of exhaust port 16 is S₁₆=πR₁₆²/4. Accordingly, from the condition of S_{g}=S₁₆, threshold value D_{G} is expressed as in the following Equation 1.

D_{G}×2(A+B)=πR₁₆²/4

D_{G}=πR₁₆²/8(A+B) Equation 1

For example, if R₁₆=4 mm, A=4 mm, and B=5 mm, D_{G}=0.314 mm.

In the first step, exhaust unit 12 and metal paste supply unit 14 are maintained in a stop state or a standby state. Exhaust unit 12 switches direction switching valve 28 to air port 31 side. Metal paste supply unit 14 maintains the open/close valve of suck-back valve 40 in the OFF state by setting the outlet side of suck-back valve 40 to the atmospheric pressure.

Next, in the second step, in exhaust unit 12, direction switching valve 28 is switched to vacuum apparatus 26 side to turn vacuum apparatus 26 ON. Meanwhile, in metal paste supply unit 14, the open/close valve of suck-back valve 40 is switched to the ON state and the suck-back function is activated such that the outlet side of suck-back valve 40 is in a depressed state with a pressure of, for example, several kPa.

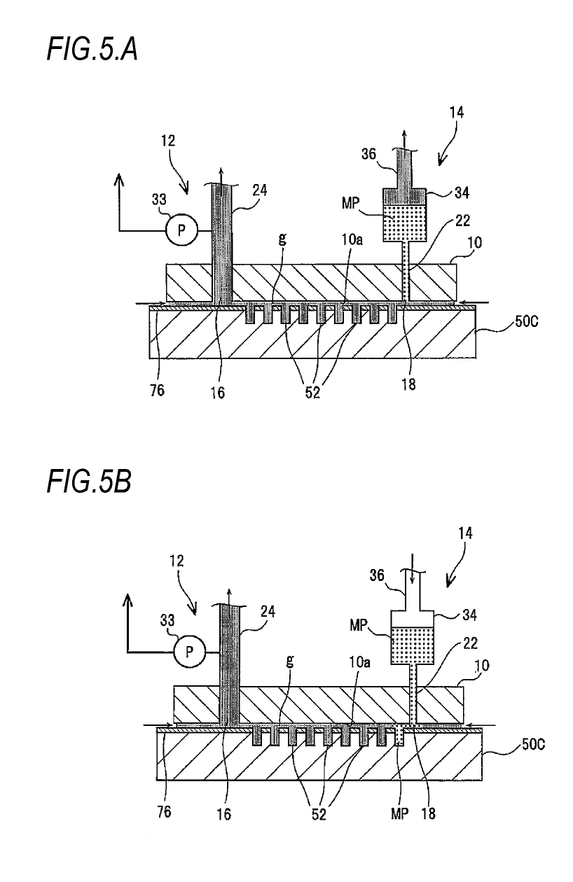

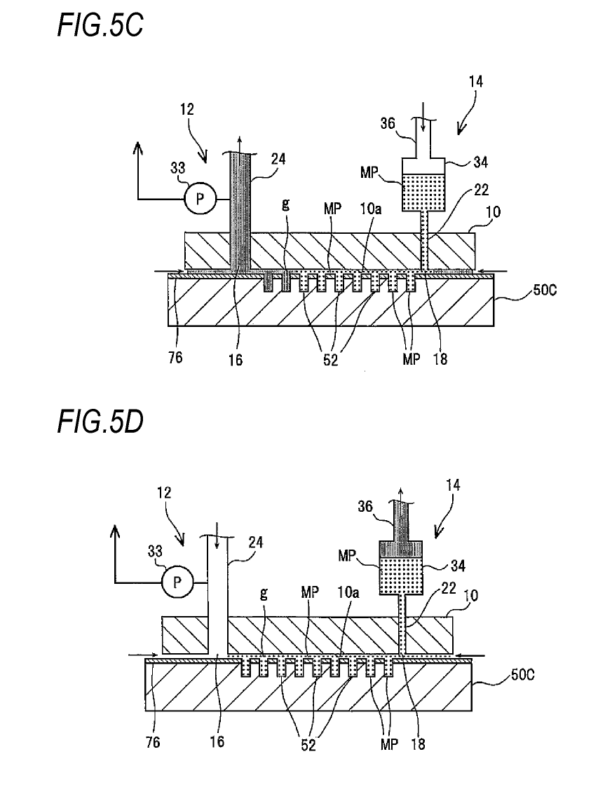

Then, as illustrated in FIG. 5A, the air within gap g formed between acting surface 10a of pad 10 and the surface of semiconductor chip 50C is discharged from exhaust port 16 by exhaust unit 12. Meanwhile, the air in the atmosphere is introduced into gap g from each side of gap g. However, as the condition of D_{g}<D_{G} is satisfied as described above, the air discharge rate from gap g exceeds the air inflow rate. As a result, the air within gap g is reduced, and the inside of gap g and hence the inside of each of non-through vias 52 are turned into a decompression state within a short time (typically, not more than several seconds). In that event, because metal paste supply unit 14 activates the suck-back function of suck-back valve 40, metal paste MP is not drown into gap g from inlet port 18.

When the inside of gap g is turned into the decompressed condition as described above, controller 30 confirms it through pressure sensor 33. In addition, controller 30 operates metal paste supply unit 14 while maintaining the exhausting operation of exhaust unit 12 as it is, thereby turning the open/close valve of suck-back valve 40 ON. Then, in metal paste supply unit 14, compressed air of a predetermined pressure (for example, 0.05 MPa to 0.7 MPa) is sent to inlet 34b of paste container 34 from compressed air supply source 38 via regulator 42 and through suck-back valve 40, thereby causing metal paste MP to be delivered from outlet 34a of paste container 34. Furthermore, as illustrated in FIG. 5B, metal paste MP delivered from paste container 34 is ejected or introduced into gap g from inlet port 18 via paste flow path 22 in pad 10.

As illustrated in FIG. 5C, metal paste MP introduced from inlet port 18 rapidly spreads in all directions within gap g in the decompressed condition, and in the process of spreading, flows into each non-through via 52 wherever it goes. In that event, because the inside of non-through via 52 is also in the decompressed condition, metal paste MP smoothly flows into non-through via 52 in such a manner that non-through via 52 is filled with metal paste MP from the bottom portion to top portion thereof without inclusion of pores or voids.

By determining a suitable timing where metal paste MP widely spreads to all non-through vias 52 within gap g, i.e. when a set time, e.g. 10 seconds, has lapsed after starting the supply of metal paste, controller 30 switches the operations of exhaust unit 12 and metal paste supply unit 14. That is, in metal paste supply unit 14, the open/close valve of suck-back valve 40 is turned OFF, the supply of metal paste MP is stopped, and the suck-back function is activated. In exhaust unit 12, direction switching valve 28 is switched to air port 31 side.

Accordingly, as illustrated in FIG. 5D, the atmospheric pressure is applied to metal paste MP filled in gap g between pad 10 and semiconductor chip 50C from exhaust port 16 as well as from each side of gap g such that the spreading or flowing of metal paste MP within gap g is stopped. In addition, even if non-through vias 52, which are not completely filled with metal paste MP at the time of stopping the supply of metal paste MP, exist, metal paste MP is fully pushed into non-through vias 52 by the atmospheric pressure applied from the surrounding (sides) and exhaust port 16. In this manner, all non-through vias 52 distributed in the surface of semiconductor chip 50C are filled with metal paste MP at once.

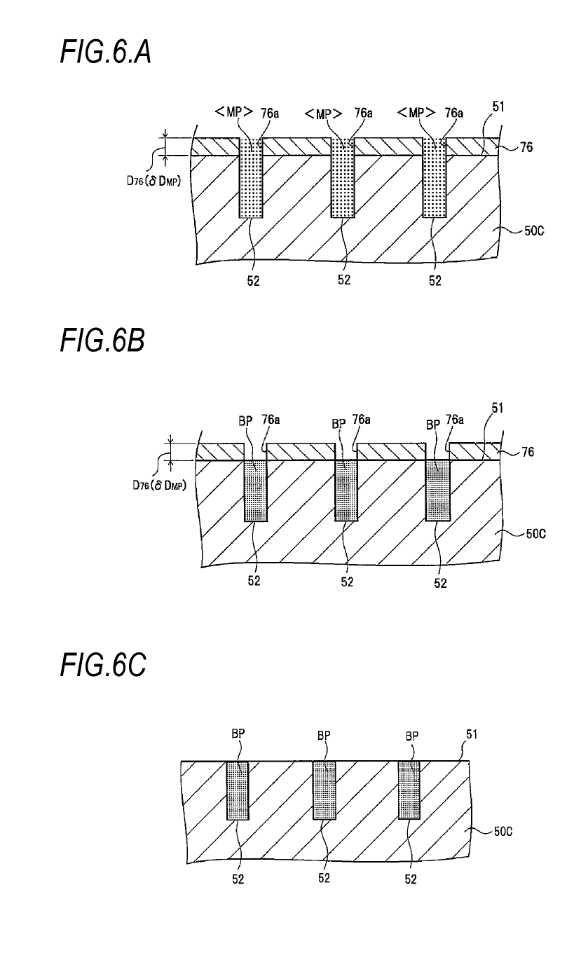

When the filling processing of metal paste as described above is terminated, pad 10 is separated from semiconductor chip 50C by a pad displacement mechanism and/or a stage displacement mechanism 74. Thereafter, metal paste M adhered to acting surface 10a of pad 10 is removed by, for example, a cleaning. Meanwhile, metal plate MP, which has overflowed to the surface of semiconductor chip 50C, is wiped by, for example, a squeezee. As a result, as illustrated in FIG. 6A, the top surface of metal paste MP filled in each of non-through vias 52 becomes substantially coplanar with the top sides of openings 76a of mask 76.

Thereafter, semiconductor chip 50C is transferred to a heating apparatus (not illustrated) where semiconductor chip 50 is subjected to a baking processing at a processing temperature of, for example, 100 to 300. With this baking processing, flux volatilizes from metal paste MP filled in each of non-through vias 52, i.e. via filling metal paste <MP>, and hence via filling metal paste <MP> is turned into solid via plugs BP.

When via filling metal paste <MP> is turned into solid via plugs BP as described above, the volume of each of solid via plugs BP contracts due to the volatilization of flux. Therefore, the top surface of via plugs BP is lowered by δD_{MP} as compared to the top surface of via filling metal paste <MP>. In the present exemplary embodiment, as illustrated in FIG. 6B, thinness D₇₆ of mask 76 is determined to ensure that the top surface of via plugs BP becomes coplanar with (at the same level as) surface 51 to be processed on semiconductor chip 50C.

That is, a contraction amount or settling amount δD_{MP} when via filling metal paste <BP> is turned into solid via plugs is determined based on test data or calculation of, for example, the kind of metal paste MP, the bore and depth of non-through vias 52, and the temperature and time period of baking processing. Therefore, thickness D₇₆ of mask 76 may be selected as a size which is the same as settling amount δD_{MP}. In this manner, when mask 76 is removed from surface 51 to be processed on semiconductor chip 50C after the baking processing is terminated, the top surface of via plugs BP fabricated in non-through vias 52 are exposed in a state where the top surface becomes coplanar with surface 51 to be processed on semiconductor chip 50C as illustrated in FIG. 6C. Accordingly, a flattening processing, for example, CMP, may not be required to conduct following the baking processing.

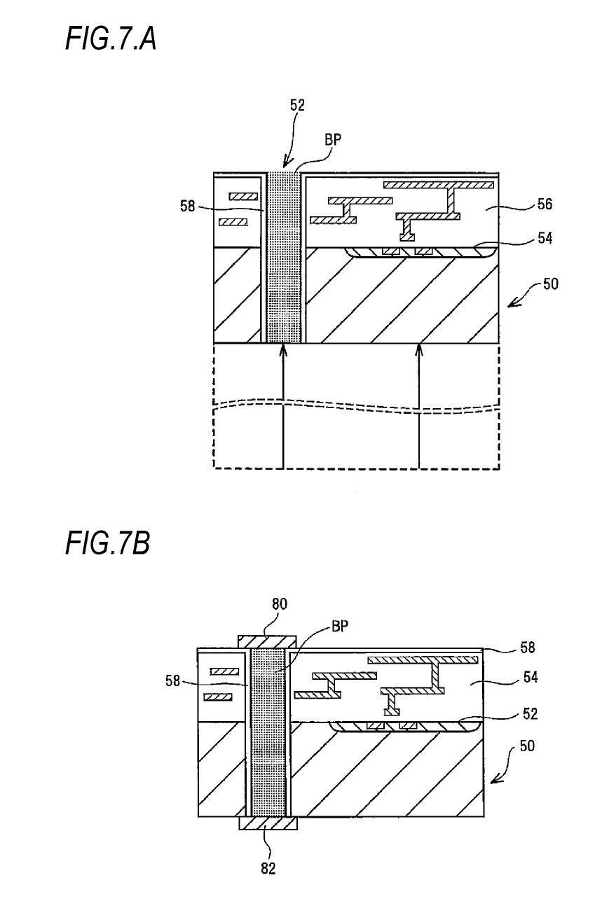

Next, as illustrated in FIG. 7A, the rear surface of semiconductor chip 50C is ablated through, for example, a gliding processing or wet etching until the bottom portions of non-through vias 52, i.e. the bottom portions of via plugs BP are exposed, thereby reducing the thickness of semiconductor chip 50C to a thickness of about 100 μm.

Next, as illustrated in FIG. 7B, metal bumps 80, 82 are formed on or attached to the top surface (front side) and bottom surface (rear side) of each via plug BP. Metal bumps 80, 82 are formed from, for example, Cu or solder. Although not illustrated, when a plurality of semiconductor chips 50C are vertically stacked, metal bumps 80, 82 are connected with corresponding bumps on another silicon substrate.

As described above, in the first aspect, all non-through vias 52 of semiconductor chips 50C may be efficiently filled with metal paste MP within a short time under an atmospheric space using a simple and convenient metal paste filling apparatus that is provided with small pad 10, of which the size is substantially the same as semiconductor chip SOC. Furthermore, since the inside of each of non-through vias 52 is decompressed and then paste MP flows into non-through vias 52, the metal paste may be filled in non-through vias 52 with a fine diameter of not more than 50 μm without a void. In addition, since mask 76 with a predetermined thickness is deposited on surface 51 to be processed on semiconductor chip 50C and then metal paste is filled in non-through vias 52 and openings of mask 76, the top surface of each solid via plug may become coplanar with processed surface 51 of semiconductor chip 50C after metal paste filled in non-through vias 52 and openings of masks 76 is turned into solid via plugs by a baking processing. Accordingly, a flattening processing (post process), for example CMP, may not be required.

### MODIFIED EXAMPLE OF FIRST ASPECT

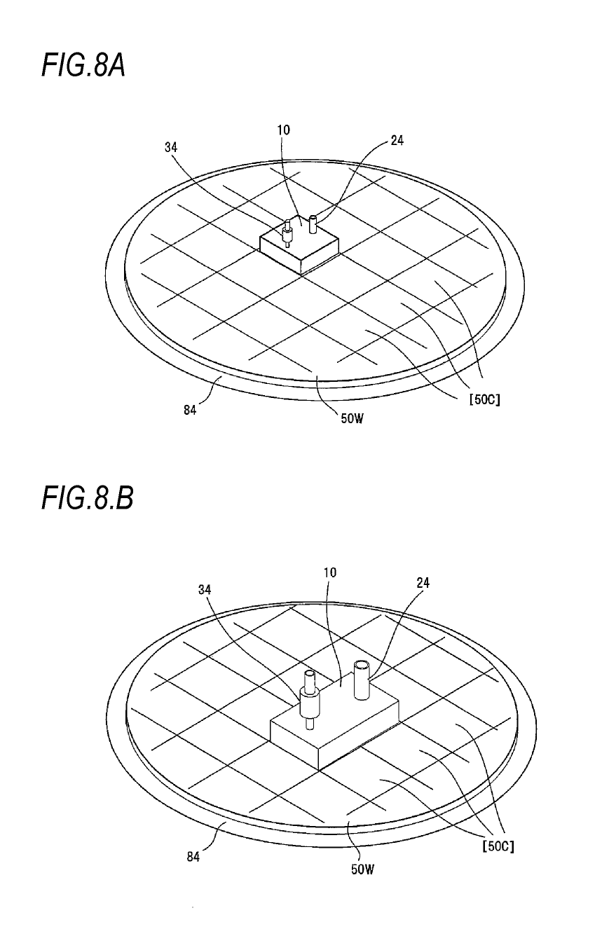

In the above-described exemplary embodiment, the workpiece is a single semiconductor (die) 50C, which is one of individual pieces cut from a semiconductor wafer. However, in the metal paste filling apparatus, metal paste filing method and via plug fabrication method in the above-described exemplary embodiment, the workpiece may be a semiconductor wafer 50W as illustrated in FIGS. 8A and 8B.

In the exemplary embodiment of FIG. 8A, pad 10 covers a cell region [50C] corresponding to one chip (die) on a semiconductor wafer 50W in one metal paste filling processing, and fills all the non-through vias 52 distributed on cell region [50C] at once in the same manner as the above-described exemplary embodiment. Semiconductor wafer 50W is fixed on a stage 60 (see FIG. 4) in a state where it is adhered to a dicing tape 84. Pad 10 is relatively displaced stepwise in an X-Y plane in relation to semiconductor wafer 50W by a pad displacement mechanism and/or stage displacement mechanism 74 in such a manner that all cell regions [50C] on semiconductor wafer 50W may be subjected to a metal paste filling processing which is the same as that in the above-described exemplary embodiment. In such a case, it is possible to conduct a contactless scanning of pad 10 while maintaining a gap distance D_{g} between acting surface 10a of pad 10 and the surface of semiconductor wafer 50W. Accordingly, scanning may be terminated without scratching the surface of semiconductor wafer 50W. In addition, even after dicing, the metal paste filling processing, which is the same as that in the above-described exemplary embodiment, may be conducted for diced semiconductor wafer 50W on dicing tape 84, i.e. individual semiconductor chips 50C.

Also, prior to dicing, as in the exemplary embodiment of FIG. 8B, pad 10 may cover a plurality of contiguous (neighboring) cell regions [50C] (two regions in the illustrated exemplary embodiment) on semiconductor wafer 50W at one metal paste filling processing so as to fill all non-through vias 52 distributed on the plural of cell regions [50C] with the metal paste at once in the same manner as the above-described exemplary embodiment. In such a case, the contactless scanning of pad 10 may also be conducted on semiconductor wafer 50W. Consequently, the processing efficiency may be enhanced.

In addition, the surface of semiconductor wafer 50W may be divided into plural regions in a matrix form or a grid form on the basis of acting surface 10a of pad 10 or by taking acting surface 10a of pad 10 as one unit, and one metal paste processing may be conducted for each divided region of one unit such that all the non-through vias existing in the divided region may be filled with the metal paste at once.

In addition, there would be no problem even if one or more non-through metal vias 52 are not filled with the metal paste sufficiently (or at all) although they are covered by acting surface 10a of pad 10 in one metal paste filling processing. In such a case, metal paste may be filled in these non-through vias 52 as set by properly displacing the positional relationship between non-through vias 52 and acting surface 10a of pad 10 in the next metal paste filling processing or in a metal filling processing to be performed later. This is also suitable for the above-described exemplary embodiment of which the workpiece is a single semiconductor chip 50C. For a similar reason, in a case where the workpiece is one single semiconductor chip 50C, there would also be no problem for the same reason even if one or more non-through vias 52 are not filled with the metal paste since they are not covered by acting surface 10a of pad 10.

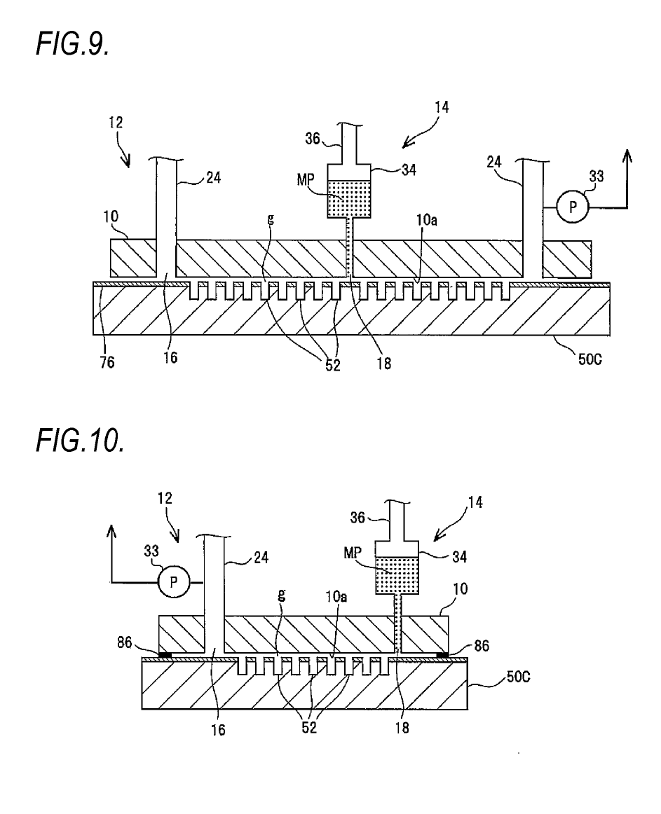

In addition, in the metal paste filling apparatus, the construction of each section may be variously modified. Especially, various modifications may be made around pad 10. Specifically, an optional layout may be made in relation to the numbers and arranged positions of exhaust ports 16 and inlet ports 18 as described above. For example, as illustrated in FIG. 9, a single inlet port 18 may be formed at the central portion of pad 10, and a plurality of exhaust ports 16 may be formed along the peripheral portion of the pad to surround inlet port 18. In contrast, although not illustrated, a single exhaust port 16 may be formed at the central portion of pad 10, and a plurality of inlet ports 18 may be formed along the peripheral portion of the pad to surround exhaust port 16.

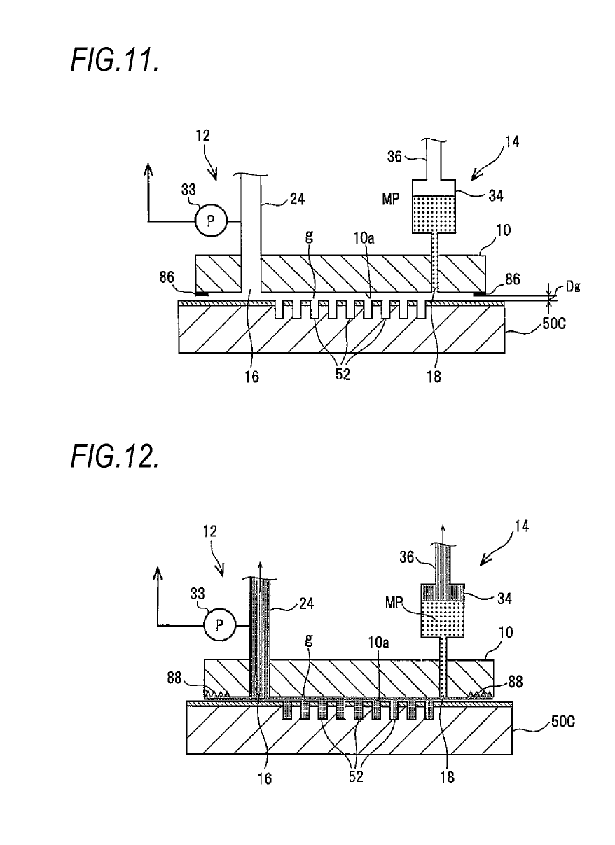

In addition, as illustrated in FIGS. 10 and 11, a configuration, in which bank parts 86 with a proper thickness (for example, not more than 0.5 mm) along the outer circumferential area of acting surface 10a of pad 10, may also be suitably employed.

Bank parts 86 may be preferably formed of a material that is excellent in slipperiness to such an extent that it is difficult for bank parts 86 to scratch the surface of substrate 50 even when bank parts 86 are in contact with the surface of substrate 50, for example, a stripe-shaped seal 86 of a fluorine resin. Accordingly, as illustrated in FIG. 10, pad 10 may be allowed to be in contact with substrate 50 and even to be relatively slid on the surface of substrate 50 in the state where bank parts 86 are in contact with the surface of substrate 50. Like this, as the bank parts 86 are in contact with the surface of substrate 50, the sides of gap g are blocked such that a vacuum condition may be more efficiently formed within gap g.

Alternatively, as illustrated in FIG. 11, acting surface 10a of pad 10 may be put over the surface of substrate 50 in such a manner that bank parts 86 may be spaced apart from the surface of substrate 50 by a distance D_{g} smaller than threshold value D_{G}. In such a case, gap g formed in the inside of bank parts 86 may also be vacuumized and the distance (height) of gap g may be increased by the height of bank parts 86.

In addition, a configuration in which labyrinth grooves 88 are formed on acting surface 10a of pad 10 as illustrated in FIG. 12 may be suitably employed. When gap g formed between acting surface 10a of pad 10 and surface of substrate 50 is decompressed, labyrinth grooves 88 may reduce conductance of air flow that is introduced into gap g from the surrounding (sides). With this arrangement, vacuumization of the inside of gap g may be more efficiently performed.

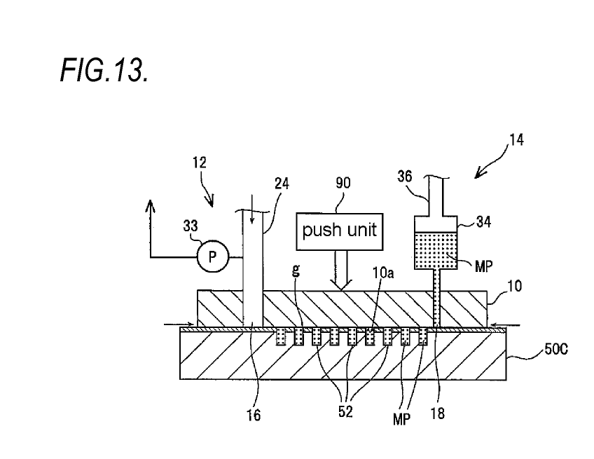

Furthermore, a configuration with a push unit 90 as illustrated in FIG. 13 may be suitably employed. In a metal paste filling processing, push unit 90 may urge acting surface 10a of pad 10 against the surface of substrate 50 directly after the supply of metal paste MP to the inside of gap g between pad 10 and substrate 50 is terminated. By urging acting surface 10a of pad 10 against the surface of substrate 50 directly after the supply of metal paste is terminated, a pressure may be applied to ensure that the inflow or embedment of metal paste MP into non-through vias within gap g. Meanwhile, a spring member may be preferably provided to give flexibility to the force for urging push unit 90. The function of push unit 90 may be provided to a pad displacement mechanism or stage displacement mechanism 74.

Exhaust unit 12 and metal paste supply unit 14 may also be variously modified. For example, in exhaust unit 12, a plurality of open/close valves may be used in place of direction switching valve 28. In metal paste supply unit 14, a piston type compressing unit may be used as a compressing unit for syringe unit 32 in place of a gas compression type compressing unit.

### [Second Aspect]

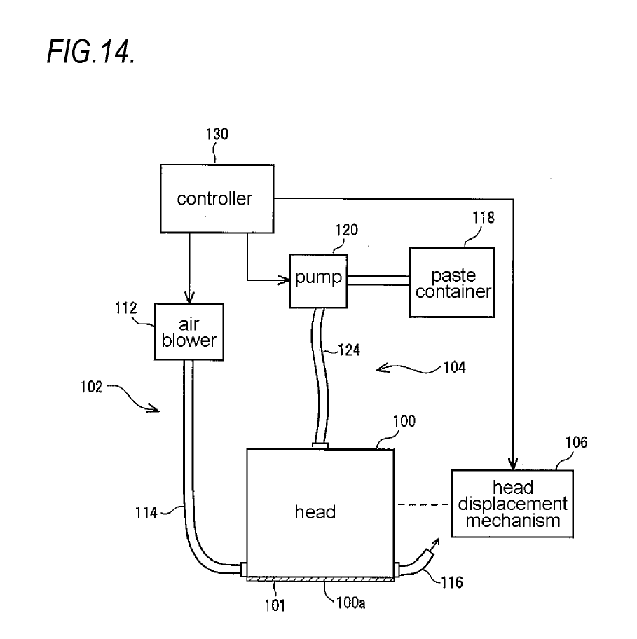

Next, the second aspect of the present disclosure will be described with reference to FIGS. 14 to 18D.

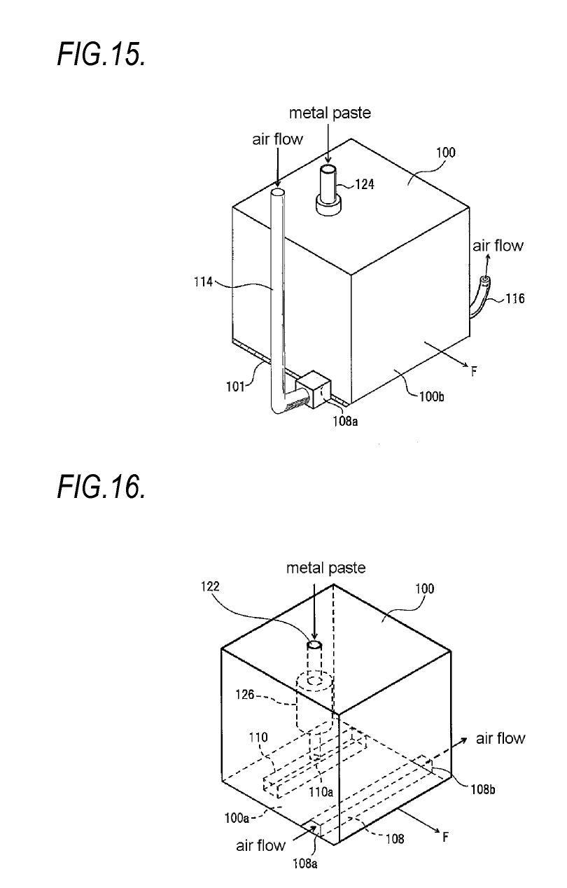

The configuration of the metal paste filling apparatus according to the second aspect is illustrated in FIG. 14. The external appearance of a head in the metal paste filling apparatus is illustrated in FIG. 15, and principle parts of the head are illustrated in FIG. 16.

The metal paste filling apparatus includes a head 100, an air flow supply unit 102, a metal paste supply unit 104, a head displacement mechanism 106, and a controller 130.

Head 100 may be formed from a rigid material that has an excellent machinability in machining a groove and an excellent maintainability, and is highly resistant against a metal paste flux, for example, from a stainless steel, an aluminum, and a resin. The constructional feature of head 100 is that head 100 has a flat bottom surface, i.e. an acting surface 100a. The acting surface 100a is formed with an air flow path 108 having a groove shape to allow suction air (nitrogen may be available) to flow therein, and a metal paste discharge port 110 having a groove shape to discharge the metal paste to the outside. In addition, a DLC (Diamond-Like Carbon) coating 100 is formed on acting surface 100a of head 100. DLC coating 101 is excellent in sildability or slide mobility in relation to a surface of a substrate.

Air flow path 108 extends across acting surface 100a of head 100 in a direction crossing the progressing direction F of head 100, preferably at right angles, near the front surface of head 100, and has an inlet 108a and an outlet 108b at the opposite ends thereof. An air flow supply unit 102 is connected to inlet 108a and outlet 108b.

Paste discharge port 110 is positioned behind air plow path 108 in progressing direction F of the head. Paste discharge port 110 extends in a direction crossing the progressing direction F of the pad 100, preferably at right angles, in a form of recess or depression, and has a paste outlet 110a at the central part thereof. A metal paste supply unit 104 is connected to paste outlet 110a. Paste discharge port 110 in the illustrated constructional example is formed in an elongated shape in parallel to air flow path 108.

Air flow supply unit 102 includes an air blower 112 that generates air flow, a flexible gas tube 114 that connects the outlet side of air blower 112 to inlet 108a of air flow path 108 of head 100, and a tap 116 connected to outside 108b. In the present exemplary embodiment, although the outlet side of air blower 112 is set as a positive pressure side, the outlet side of air blower 112 may be set as a negative pressure side. In such a case, inlet 108a and outlet 108b of air flow path 108 will be reversed.

Metal paste supply unit 104 includes a container 118 that stores metal paste (MP), a pump 120 that draws up metal paste MP from container 118 and pumps metal paste MP, and a paste supply tube 124 that connects the outlet side of pump 120 to a paste inlet port 122 formed on the top side of head 100. Pump 120 may include, for example, a syringe pump. In the inside of head 100, a buffer portion 126 is formed between paste inlet port 122 and the paste outlet 110a to temporarily accumulate metal paste MP.

A head displacement mechanism 106 supports head 100, and performs, for example, positioning, opposite locating, scanning, and separating of head 100 in relation to a substrate to be processed. A stage displacement mechanism 74 (see FIG. 4) may be provided to be used together with head displacement mechanism 106, or to be used in place of head displacement mechanism 106.

Controller 130 includes a microcomputer and a required interface or a peripheral device, and controls an action or condition of each of the units in the metal paste filling apparatus, and the sequence of the entirety of the apparatus.

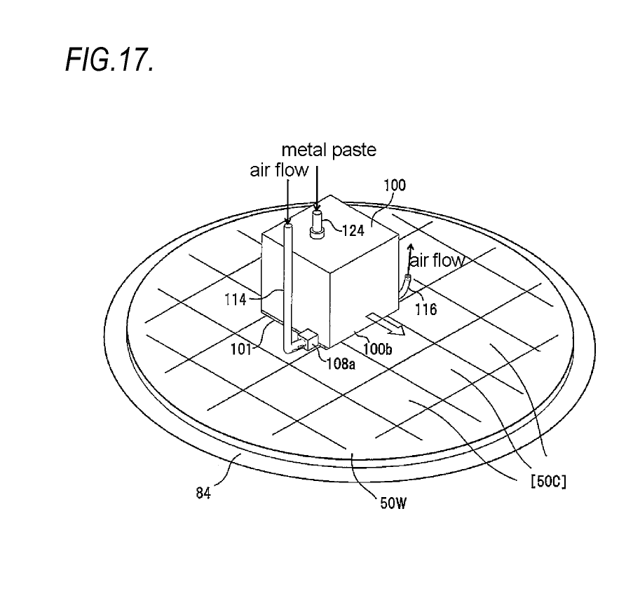

The metal paste filling apparatus according to the present exemplary embodiment may take a semiconductor wafer 50W prior to dicing as a proper workpiece as illustrated in FIG. 17. In such a case, controller 130 controls head displacement mechanism 106 and/or stage displacement mechanism 74 so as to scan head 100 on semiconductor wafer 50W. In head scanning, acting surface 100a of head 100 is in contact with the surface of semiconductor wafer 50W. However, since acting surface 100a is formed with DLC coating 101, the scanning is terminated without substantially damaging the surface of semiconductor wafer 50W. Furthermore, since a mask 76 is deposited to the surface of semiconductor wafer 50W, the to-be-processed surface of the wafer below mask 76 is not scratched at all. During the head scanning, controller 130 continuously operates air flow supply unit 102 and metal paste supply unit 104 in the ON state.

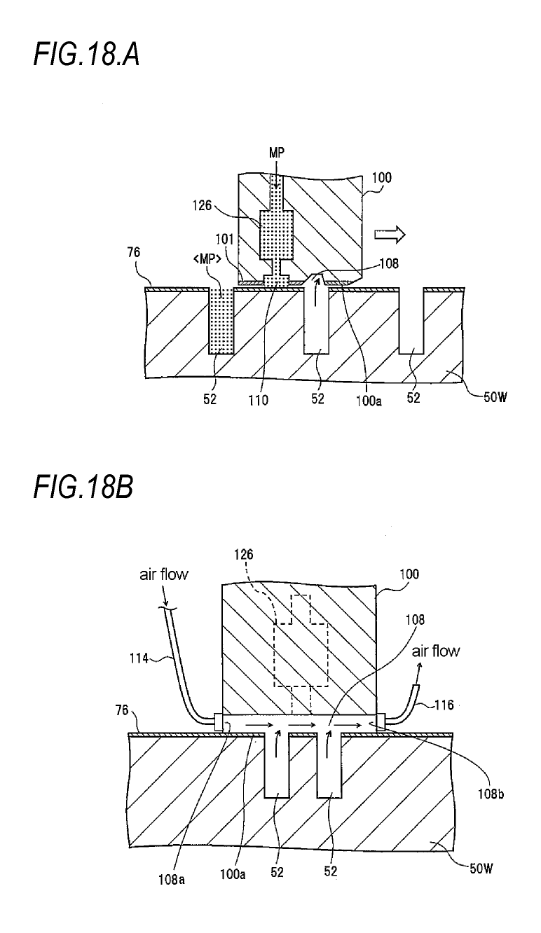

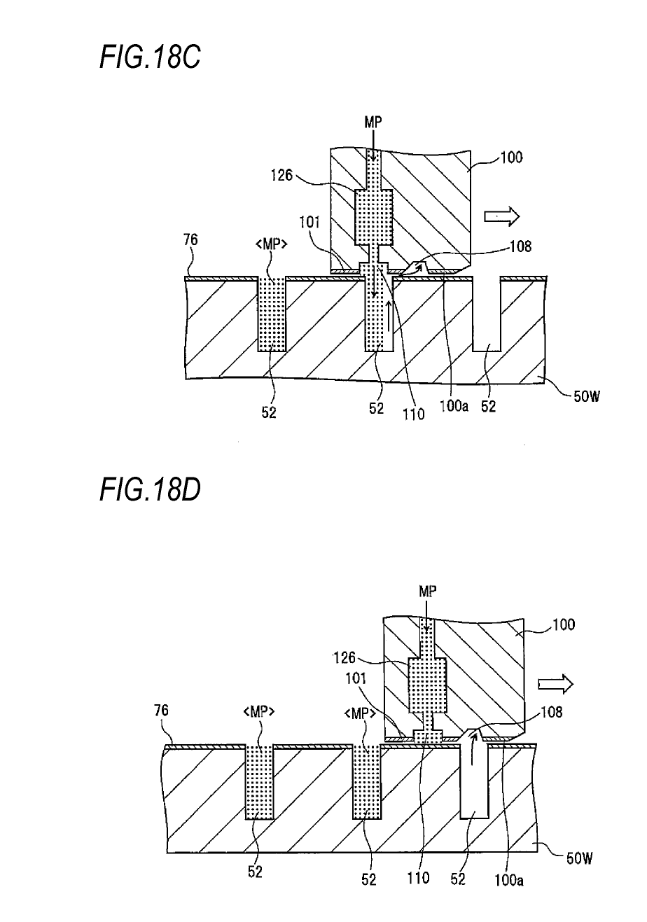

As illustrated in FIG. 18A, in the process of moving head 100 forward on semiconductor wafer 50W, air flow path 108 positioned at front part of acting surface 100a passes first above each non-through via 52 existing wherever acting surface 100a moves. In that event, since air flow supplied from air flow supply unit 102 escapes air flow path 108 from inlet 108a to outlet 108b of air flow path 108 as illustrated in FIG. 18B, the air within non-through vias 52 just below air flow path 108 is discharged (suctioned) upward due to the venturi effect such that the inside of non-through vias 52 is decompressed.

Since acting surface 100a of head 100 covers the openings of non-through vias 52 even after air flow path 108 of acting surface 100a of head 100 has passed over decompressed non-through vias 52, air does not substantially enter non-through vias 52 from the outside. Rather, the decompressed condition is improved or maintained by the venturi effect. As illustrated in FIG. 18C, paste discharge port 110 of acting surface 100a of the head passes over non-through vias 52 which maintain the decompressed condition as described above. In that event, metal paste MP flows from paste discharge port 110 into non-through vias 52 in the manner of being suctioned. In this manner, non-through vias 52 are filled with metal paste MP. As illustrated in FIG. 18D, a series of actions as described above are repeated for all non-through vias 52 over which head 100 passes.

Also in the present exemplary embodiment, when the metal paste filling processing as described above is completed, head 100 is separated from semiconductor wafer 50W by head displacement mechanism 106 and/or stage displacement mechanism 74. Thereafter, metal paste MP adhered to acting surface 100a of head 100 is removed by, for example, a cleaning. Meanwhile, metal paste MP that has overflowed to the surface of semiconductor wafer 50W is wiped by, for example, a squeezee. As a result, as in FIG. 6A, the top surface of metal paste MP filled in each of non-through vias 52 becomes substantially coplanar with the top surfaces of openings 76a of mask 76.

Then, semiconductor wafer 50W is transported to a heating apparatus (not illustrated) where semiconductor wafer W is subjected to a baking processing at a temperature of, for example 100 to 300. With this baking processing, flux volatilizes from the metal paste filled in each of non-through vias 52, i.e. vial filling metal paste <MP> such that via filling metal paste <MP> is turned into solid via plugs BP.

Also in the present exemplary embodiment, thickness D₇₆ of mask 76 is determined in such a manner that when mask 76 is removed from processed surface 51 of semiconductor wafer 50W after the baking processing is terminated, the top surface of each of via plugs BP fabricated in non-through vias 52 becomes coplanar with surface 51 to be processed on semiconductor wafer 50W and are exposed as in FIG. 6C. Accordingly, a flattening processing, for example, CMP, may not be required to perform following the baking processing.

Next, as in FIG. 7A, for example, the rear surface of semiconductor wafer 50C is ablated through, for example, a gliding processing or wet etching until the bottom portions of non-through vias 52, i.e. the bottom portions of via plugs BP are exposed, thereby reducing the thickness of semiconductor wafer 50W to a thickness of about 100 μm. As in FIG. 7B, metal bumps 80, 82 are formed on or attached to the top surface (front side) and bottom surface (rear side) of each of via plugs BP, respectively. Metal bumps 80, 82 are formed from, for example, Cu or a solder.

As described above, also in the second aspect, all non-through vias 52 of semiconductor wafer 50W may be efficiently filled with metal paste MP within a short time under an atmospheric space using a simple and convenient metal paste filling apparatus that is provided with small head 100, of which the size is substantially smaller that semiconductor wafer 50W. Furthermore, since the inside of each of non-through vias 52 is decompressed and then metal paste MP flows into decompressed non-through vias 52, metal paste may be filled in non-through vias 52 with a fine diameter of not more than 50 μm without producing a void. In addition, since mask 76 with a predetermined thickness is deposited on surface 51 of semiconductor wafer 50W to be processed and then metal paste is filled in non-through vias 52 and openings of mask 76, the top surface of solid via plugs may become coplanar with processed surface 51 of semiconductor wafer 50W after metal paste filled in non-through vias 52 and openings of masks 76 is turned into solid via plugs by a baking processing. Accordingly, a flattening processing (post process), for example CMP, may not be required.

### Other Exemplary Embodiment or Modified Embodiment

In the above-described exemplary embodiments, in a via-last TSV fabrication process, via plugs BP are fabricated by filling a metal paste in non-through vias 52 distributed in the surface of a silicon substrate 50, and then the thickness of substrate 50 is reduced until the bottom portions of non-through vias 52, i.e. the bottom portions of via plugs BP are exposed from the rear side of the substrate. That is, non-through vias 52 were in a non-through state when they are subjected to a metal paste filling processing, and are finally turned into through vias.

However, the metal paste filling method, metal paste filling apparatus, and via plug fabrication method are not limited to the application to the TSV fabrication process. For example, the present disclosure is also applicable to a case where a via plug is fabricated in a via which is permanently a non-through via formed on a side of a silicon substrate for internal wiring. Moreover, the present disclosure may adopt a non-via hole with a bore formed in a substrate other than a silicon substrate as an object to be subjected to the metal paste processing or a via plug fabrication processing.

In addition, in the present disclosure, a layer (wall portion) in which a non-through bore is perforated and a base layer of the non-through via (non-through hole) may be different from each other.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A method of filling a metal paste in one or more non-through holes formed in a surface of a substrate, the method comprising:
locating an acting surface of a pad opposite to the surface of the substrate with a gap therebetween in such a manner that the acting surface of the pad covers at least one of the non-through holes, the gap being smaller than a predetermined threshold value in relation to the surface of the substrate;
decompressing the inside of the gap by discharging the air in the gap from one or more exhaust ports formed in the acting surface of the pad; and
supplying the metal paste from one or more inlet ports formed in the acting surface of the pad to all or some of the non-through holes existing in the gap.

2. The method of claim 1, wherein the threshold value is a gap distance when the total of side area of the gap formed between the acting surface of the pad and the surface of the substrate becomes the total of bore area of the exhaust ports.

3. The method of claim 1, wherein in the metal paste supplying step, an exhaust operation through the exhaust ports is continued until the metal paste widely spreads to the all or some of the non-through holes within the gap, and the exhaust operation is stopped after the metal paste widely spreads to all or some of the non-through holes within the gap.

4. The method of claim 3, wherein in the metal paste supplying step, the exhaust ports are opened to the atmosphere just after or simultaneously when the exhaust operation is stopped.

5. The method of claim 1, wherein just after the metal paste supplying step is terminated, the acting surface of the pad is urged against the surface of the substrate.

6. The method of claim 1, wherein the substrate is a single semiconductor chip cut from a semiconductor wafer as an individual piece, and
wherein in the acting surface locating step, the pad covers all or some of the non-through holes formed on the surface of the semiconductor chip, in the decompressing step, all or some of the non-through holes of the semiconductor chip are decompressed, and in the metal paste supplying step, the metal paste is filled in all or some of the non-through holes of the semiconductor chip at once.

7. The method of claim 1, wherein the substrate is a semiconductor wafer, and
wherein in the acting surface locating step, the pad covers all or some of the non-through holes formed in one cell region or a plurality of continued cell regions on the semiconductor wafer, in the decompressing step, the inside of all or some of the non-through holes in the cell region(s) are decompressed, and in the metal paste supplying step, the metal paste is filled in all or some of the non-through holes in the cell region(s) at once.

8. The method of claim 1, wherein the substrate is a semiconductor wafer, and
wherein in the acting surface locating step, the pad covers all or some of the non-through holes formed in a divided region of one unit on the semiconductor wafer when the semiconductor wafer is divided in a matrix form with reference to the acting surface of the pad, and in the metal paste supplying step, the metal paste is filled in all or some of the non-through holes in the divided region of one unit at once.

9. The method of claim 1, wherein the bore of the non-through holes is in the range of 5 μm to 50 μm.

10. The method of claim 1, wherein the metal paste contains metal nano-particles.

11. A method of fabricating a via plug of a conductor in one or more non-through vias formed in a surface of a substrate, comprising:
depositing a mask on a surface of the mask to be processed, where the mask is formed with one or more openings at the positions superimposed with the non-through vias, and the bore of the openings is the same as that of the non-through vias;
filling a metal paste in each of the non-through vias from the bottom portion to the top portion thereof;
baking the metal paste filled in the non-through vias by heating the substrate at a predetermined temperature such that the metal paste is turned into one or more solid via plugs; and
removing the mask from the surface of the substrate to be processed.

12. The method of claim 11, wherein the metal paste filling step includes:
locating an acting surface of a pad opposite to the surface of the substrate with a gap smaller than a predetermined threshold value in relation to the surface of the substrate in such a manner that the acting surface covers at least one of the non-through holes;
decompressing the inside of the gap by discharging the air in the gap from one or more exhaust ports formed in the acting surface of the pad; and
supplying the metal paste from one or more inlet ports formed in the acting surface of the pad to all or some of the non-through holes existing in the gap.

13. The method of claim 11, wherein the metal paste filling step includes:
locating an acting surface of a head opposite to the surface of the substrate, where the acting surface of the head is formed with a gas flow path of a groove shape configured to allow a suction gas to flow therein, and a paste discharge port of a groove shape configured to discharge the metal paste;
supplying gas flow from the outside to let the gas flow out of the gas flow path;
compressing and supplying the metal paste to the paste discharge port; and
relatively sliding the head on the surface of the substrate in such a manner that the gas flow path passes over at least a part of the non-through vias of the substrate first to decompress the insides of the non-through vias by the venturi effect, and then the paste discharge port passes over the non-through vias to fill the metal paste in the insides of the non-through vias.

14. The method of claim 11, wherein the thickness of the mask is determined in such a manner that the metal paste filled in the non-through vias from the bottom portion thereof to the top portion of the openings of the mask is contracted by the metal paste baking step to a height where the top surface of the metal paste filled in the non-through vias becomes coplanar with the surface of the substrate to be processed.

15. An apparatus of filling a metal paste in one or more non-through holes formed in a surface of substrate, the apparatus comprising:
a pad including an acting surface that is located opposite to the surface of the substrate with a gap smaller than a predetermined threshold value in relation to the surface of the substrate in such a manner that the acting surface covers at least one of the non-through vias;
an exhaust unit including one or more exhaust ports formed in the acting surface of the pad, and configured to discharge the air within the gap through the exhaust ports to decompress the inside of the gap; and
a metal paste supply unit including one or more inlet ports formed in the acting surface of the pad, and configured to supply the metal paste from the inlet ports to all or some of the non-through holes existing in the gap.

16. The apparatus of claim 15, wherein the acting surface of the pad is flat.

17. The apparatus of claim 15, wherein the exhaust unit includes:
a gas flow path extending through the pad to be connected with the exhaust ports; and
a vacuum apparatus connected with the gas flow path through an exhaust tube.

18. The apparatus of claim 17, wherein a switching valve is installed in the way of the exhaust tube so as to selectively connect the exhaust ports to one of the vacuum apparatus or an air port.

19. The apparatus of claim 15, wherein the metal paste supply unit includes:
a paste flow path extending through the pad to be connected with the inlet ports; and
a syringe unit configured to compress and supply metal paste to the paste flow path through a paste supply tube.

20. The apparatus of claim 19, wherein the syringe unit includes:
a paste container including an outlet connected to the paste flow path and an inlet formed opposite to the outlet, and configured to accommodate a metal paste; and
a compressed gas supply source connected to the inlet of the paste container through a gas tube.

21. The apparatus of claim 20, wherein the syringe unit includes a suck-back valve installed in the way of the gas tube.

22. The apparatus of claim 15, wherein a bank part is formed on the acting surface of the pad to surround at least a part of the non-through holes of the substrate when the pad is located to be opposite to the substrate with the gap therebetween.

23. The apparatus of claim 22, wherein the bank part protrudes from the acting surface of the pad with a height of not more than 0.5 mm.

24. The apparatus of claim 23, wherein the bank part has a slidability characteristic in relation to the substrate.

25. The apparatus of claim 15, wherein a labyrinth groove is formed on the acting surface of the pad to surround at least a part of the non-through vias of the substrate when the pad is located to be opposite to the substrate with the gap therebetween.

26. The apparatus of claim 15, further comprising a displacement mechanism to conduct relative positioning, opposite locating, and separating between the substrate and the pad.

27. A method of filling a metal paste in one or more non-through holes formed in a surface of a substrate, the method comprising:
locating an acting surface of a head opposite to the surface of the substrate, where the acting surface of the head is formed with a gas flow path of a groove shape configured to allow a suction gas to flow therein, and a paste discharge port of a groove shape configured to discharge the metal paste to the outside;
supplying gas flow from the outside to let the gas flow out of the gas flow path;
compressing and supplying the metal paste to the paste discharge port; and
relatively sliding the head on the surface of the substrate in such a manner that the gas flow path passes over at least one of the non-through vias of the substrate first to decompress the inside of the at least one non-through via by the Venturi effect, and then the paste discharge port passes over the at least one non-through via to fill the metal paste in the inside of the at least one non-through via.

28. An apparatus of filling a metal paste in one or more non-through holes formed in a surface of a substrate, the apparatus comprising:
a head including an acting surface that is formed with a gas flow path of a groove shape configured to allow a suction gas to flow therein, and a paste discharge port of a groove shape configured to discharge the metal paste to the outside;
a gas flow supply unit configured to supply gas flow from the outside to let the gas flow out of the gas flow path;
a metal paste supply unit configured to compress and supply the metal paste to the paste discharge port; and
a displacement mechanism configured to relatively slide the head on the surface of the substrate in such a manner that the gas flow path passes over at least one of the non-through vias of the substrate first to decompress the inside of the at least one non-through via by the Venturi effect, and then the paste discharge port passes over the at least one non-through via to fill the metal paste in the inside of the at least one non-through via.
